(19) United States
(12) Patent Application Publication
(10) Pub. No.: US 2016/0351456 A1
(43) Pub. Date: Dec. 1, 2016

(54) TEST PATTERN STRUCTURE FOR MONITORING SEMICONDUCTOR FABRICATION PROCESS

(71) Applicant: Macronix International Co., Ltd., Hsinchu (TW)

(72) Inventors: Yu Neng YEH, Shetou Township (TW); Wen Cheng HUANG, Beidou Township (TW); Chia Yang LI, Hsinchu City (TW)

(73) Assignee: Macronix International Co., Ltd.

(21) Appl. No.: 14/722,336

(22) Filed: May 27, 2015

(51) Int. Cl. H01L 21/66; H01L 23/528; H01L 21/768; H01L 23/522

(52) U.S. Cl. CPC H01L 22/14; H01L 23/5221; H01L 23/5283; H01L 21/768

(57) ABSTRACT

A test pattern structure includes a substrate, a first layer formed over the substrate and including a plurality of box-shaped portions, and a second layer formed over the first layer and including a line portion that continuously extends across centers of the box-shaped portions.

### FIELD OF THE DISCLOSURE

The present disclosure relates to a test pattern structure and, more particularly, to a test pattern structure for monitoring a semiconductor fabrication process.

### BACKGROUND

In a semiconductor fabrication process, a semiconductor wafer typically includes a plurality of chip regions each having a predetermined electronic circuit structure and formed in a matrix, and a plurality of scribe line regions surrounding the chip regions. A plurality of test structures are formed within the scribe line regions during the fabrication process. The test structures are used to monitor for existence of defects within the semiconductor wafer, thus monitoring the fabrication process of the semiconductor wafer.

### SUMMARY

According to an embodiment of the disclosure, a test pattern structure includes a substrate, a first layer formed over the substrate and including a plurality of box-shaped portions, and a second layer formed over the first layer and including a line portion that continuously extends across centers of the box-shaped portions.

According to another embodiment of the disclosure, a method for monitoring existence of cut-offs within a layer is provided. The method includes forming a test pattern structure within a scribe line region of a semiconductor wafer. The forming the test pattern structure includes forming a first layer over a substrate, the first layer including a plurality of box-shaped portions, and forming a second layer over the first layer, the second layer including a line portion that continuously extends across centers of the box-shaped portions. The method also includes applying a voltage between opposite ends of the line portion of the second layer, measuring a resistance between the opposite ends of the line portion of the second layer, and determining whether a cut-off exists within the line portion of the second layer based on the measured resistance.

According to a further embodiment of the disclosure, a semiconductor wafer includes a chip region, a scribe line region surrounding the chip region, and a test pattern structure formed in the scribe line region. The test pattern structure includes a substrate, a first layer formed over the substrate and including a plurality of box-shaped portions, and a second layer formed over the first layer and including a line portion that continuously extends across the centers of the box-shaped portions.

The accompanying drawings, which are incorporated in and constitute a part of this specification, illustrate disclosed embodiments and, together with the description, serve to explain the disclosed embodiments.

### BRIEF DESCRIPTION OF THE DRAWINGS

FIG. 1 schematically illustrates a cross-sectional view of a semiconductor device during a fabrication process.

FIG. 2A schematically illustrates a top view of a test pattern structure, according to an embodiment of the disclosure.

FIG. 2B schematically illustrates a cross-sectional view of he test pattern structure of FIG. 2A taken along section line A-A′ of FIG. 2A.

FIG. 3A schematically illustrates a top view of a test pattern structure with a cut-off portion, according to an embodiment of the disclosure.

FIG. 3B schematically illustrates a cross-sectional view of the test pattern structure of FIG. 3A taken along section line B-B′ of FIG. 3A.

FIG. 4 schematically illustrates a test system for monitoring the existence of cut-offs within a layer of a test pattern structure, according to an embodiment of the disclosure.

FIG. 5 schematically illustrates a plan view of a semiconductor wafer formed with a plurality of test pattern structures, according to an embodiment of the disclosure.

### DETAILED DESCRIPTION

Reference will now be made in detail to the present embodiments, examples of which are illustrated in the accompanying drawings. Wherever possible, the same reference numbers will be used throughout the drawings to refer to the same or like parts.

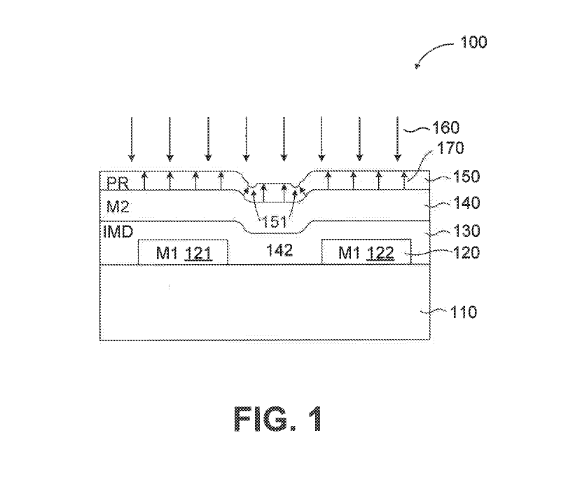

FIG. 1 is a cross-sectional view of a semiconductor device 100 during a fabrication process. Referring to FIG. 1, semiconductor device 100 includes a substrate 110 having an electronic circuit structure (not illustrated) formed thereon. Although not shown in FIG. 1, substrate 110 can include one or more N-type doped regions, P-type doped regions, dielectric layers, polysilicon layers, and metal layers, etc. A first metal (M1) layer 120, an inter-metal dielectric (IMD) layer 130, and a second metal (M2) layer 140 are sequentially formed over a top surface of substrate 110. M1 layer 120 is patterned to include a first M1 portion 121 and a second M1 portion 122. Due to the thickness of first and second M1 portions 121 and 122 underneath M2 layer 140, step portions are formed in M2 layer 140 that correspond to edges of first M1 portion 121 and second M1 portion 122. A photoresist (PR) layer 150 is formed over M2 layer 140. Selected regions of PR layer 150 are exposed to an incident light 160 via a photomask (not illustrated), During the exposure of PR layer 150, some incident light 160 is reflected by M2 layer 140 to become reflected light 170. Some reflected light 170 concentrates at portions 151 of PR layer 150 around the step portions of M2 layer 140, resulting in damage of portions 151 of PR layer 150. As a result, the damaged portions 151 of PR layer 150 may expose a portion of M2 layer 140 to a subsequently process, such as an etching process, resulting in one or more discontinuities (i.e., cut-offs) within M2 layer 140. It is desirable to monitor the existence of cut-offs within M2 layer 140, in order to monitor and improve the fabrication process of semiconductor device 100.

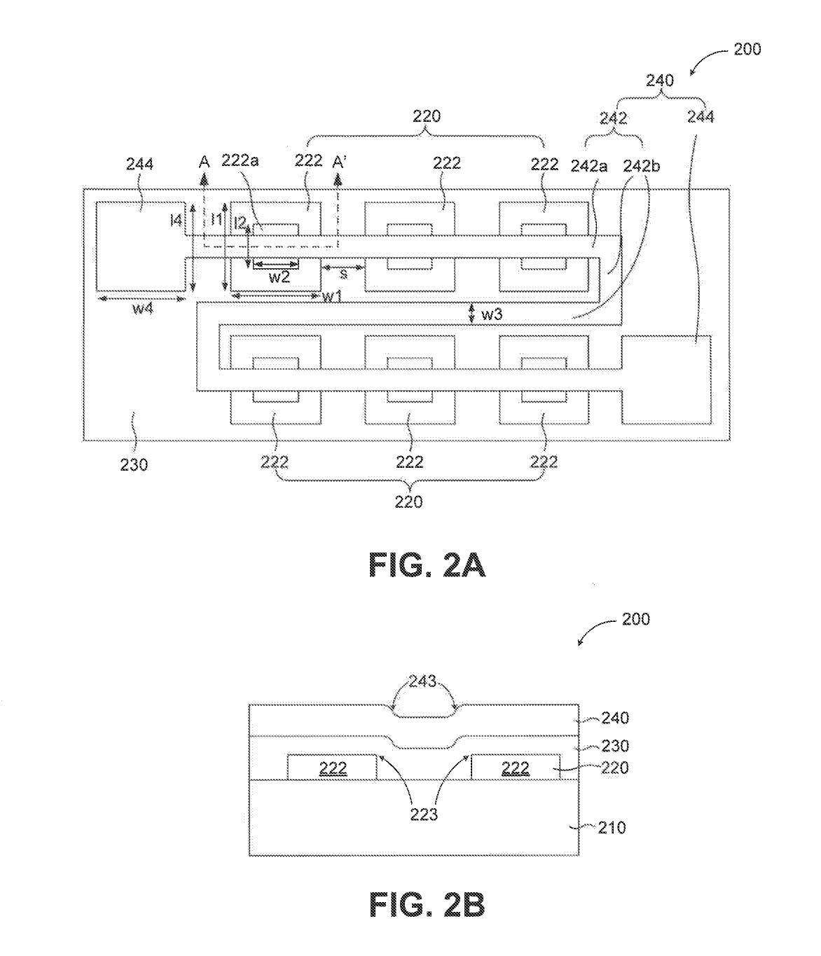

FIGS. 2A and 2B schematically illustrate a test pattern structure 200 for monitoring the existence of cut-offs within an electrically conductive layer, according to an embodiment of the disclosure. FIG. 2A is a top view of test pattern structure 200. FIG. 2B is a cross-sectional view of test pattern structure 200 taken along section line A-A′ of FIG. 2A.

Referring to FIGS. 2A and 2B, test pattern structure 200 includes a substrate 210. A first layer 220, an insulation layer 230, and a second layer 240 are sequentially formed over a surface of substrate 210. Substrate 210 can be formed of a bulk silicon material, an epitaxial layer, a silicon-on-insulator material, or a glass material, etc. First layer 220 can be made of any material that is included in a semiconductor device, such as a semiconductor material, a metal, a metal alloy, a polysilicon, an insulating material. Insulation layer 230 can be made of one or more insulating materials, such as low-k dielectric material, oxide, silicon nitride, silicon oxynitride, and silicon carbide, etc. Second layer 240 can be made of one or more electrically conductive materials, such as metal, a highly-doped semiconductor, or polysilicon.

First layer 220 includes a plurality of box-shaped portions 222 spaced apart from each other and arranged in rows and columns. Each box-shaped portion 222 includes an opening 222a. Second layer 240 includes a line portion 242 and two terminal portions 244 disposed at opposite ends of line portion 242. Line portion 242 includes a plurality of crossing lines 242a and a plurality of interconnect lines 242b. Each crossing line 242a extends across the centers of a corresponding row of box-shaped portions 222. Interconnect lines 242b electrically connect crossing lines 242a. As a result, line portion 242 of second layer 240 is formed in a serpentine structure that continuously extends over the centers of box-shaped portions 222 of first layer 220.

It is noted that the elements shown in FIGS, 2A and 2B are not necessarily drawn to scale. For example, even though box-shaped portions 222 in FIG. 2A have a square shape, box-shaped portions 222 can have a rectangular shape. In addition, a width w1 and length l1 of each box-shaped portion 222 of first layer 220, a width w2 and length l2 of each opening 222a, a space s between adjacent box-shaped portions 222 of first layer 220, a line width w3 of line portion 242 of second layer 240, and a width w4 and length l4 of terminal portions 244 of second layer 240 can be different in scale from the ones illustrated in FIG. 2A. Moreover, box-shaped portions 222 can have a shape other than the rectangular shape, such as a circular shape, a triangular shape, or a polygon shape. In addition, the number and arrangement of box-shaped portions 222 can be different from the ones illustrated in FIG. 2A.

Due to the thickness of box-shaped portions 222 of first layer 220, step portions 243 are formed in second layer 240 and correspond to edges 223 of box-shaped portions 222 of first layer 220. As explained with respect to FIG. 1, during a photolithography process, step portion 243 can cause reflected light to concentrate at a photoresist layer (not illustrated) formed above second layer 240. As a result, cut-offs may be formed within second layer 240.

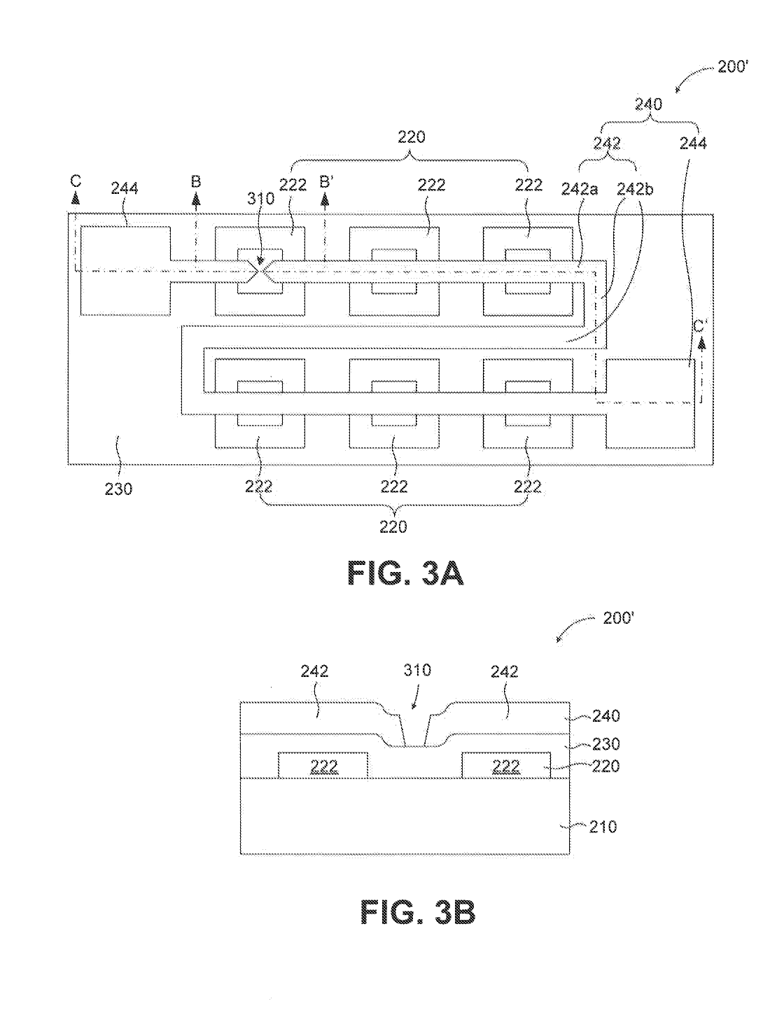

FIGS. 3A and 3B schematically illustrate a test pattern structure 200′ with a cut-off portion 310, according to an embodiment of the disclosure. FIG. 3A is a top view of test pattern structure 200′. FIG. 38 is a cross-sectional view of test pattern structure 200′ taken along section line B-8′ of FIG. 3A.

Referring to FIGS. 3A and 3B, test pattern structure 200′ has the same structure as test pattern structure 200 of FIGS. 2A and 28. That is, test pattern structure 200′ has the same components arranged in the same manner as test pattern structure 200. Cut-off portion 310 is formed within line portion 242 of second layer 240, at a position between adjacent box-shaped portions 222. Cut-off portion 310 is formed through the entire depth of second layer 240, such that the line portions 242 at opposite sides of cut-off portion 310 are not electrically connected with each other. As a result, terminal portions 244 are electrically disconnected from each other.

Although cut-off portion 310 in FIG. 3A is formed between two adjacent box-shaped portions 222, cut-off portion 310 can be formed at a different location. For example, cut-off portion 310 can be formed at the center of one of the plurality of box-shaped portions 222. As another example, cut-off portion 310 can be formed within one of interconnect line 242b between two adjacent rows of box-shaped portions 222.

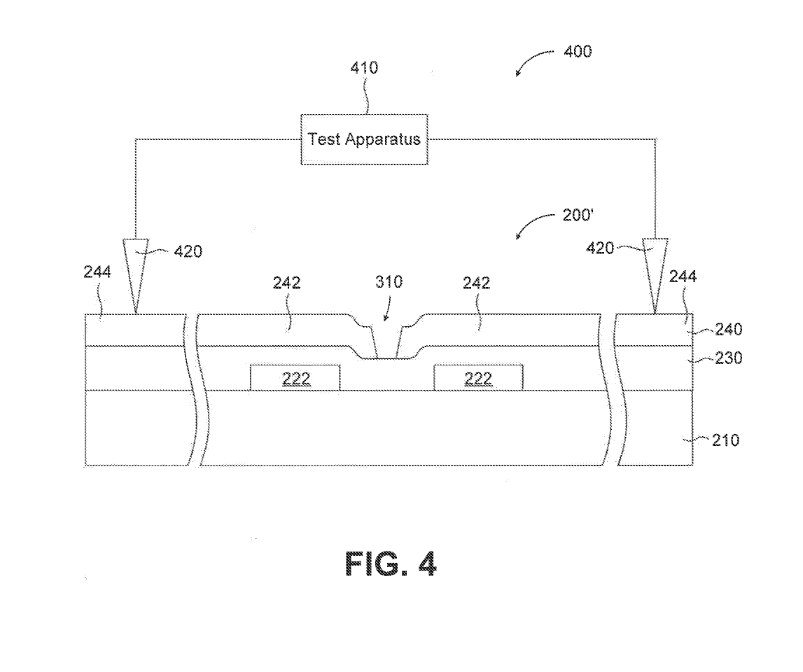

FIG. 4 schematically illustrates a test system 400 for monitoring for the existence of cut-offs within second layer 240 of test pattern structure 200′ of FIGS. 3A and 3B during a wafer acceptance test (WAT), according to an embodiment of the disclosure.

Referring to FIG. 4, test system 400 includes a test apparatus 410 coupled to test probes 420. Test probes 420 respectively contact terminal portions 244 of second layer 240 of test pattern structure 200′. During the wafer acceptance test (WAT), test apparatus 410 applies a voltage between terminals portions 244 of second layer 240 via test probes 420, and measures a resistance between terminals portions 244 via test probes 420, If the measured resistance is greater than a predetermined resistance value, test apparatus 410 determines that a cut-off portion exists within line portion 242 of second layer 240. Test apparatus 410 can output a signal indicating that a cut-off portion exists. In response to the signal, an operator can visually inspect the semiconductor wafer to confirm the existence of the cut-off region, and/or adjust process parameters, such as the thickness of photoresist, exposure time, exposure energy, etc., in order to prevent formation of the cut-off region in future processes. Otherwise, if the measured resistance is less than or equal to the predetermined resistance value, test apparatus 410 determines that no cut-off portion exists within line portion 242 of second layer 240.

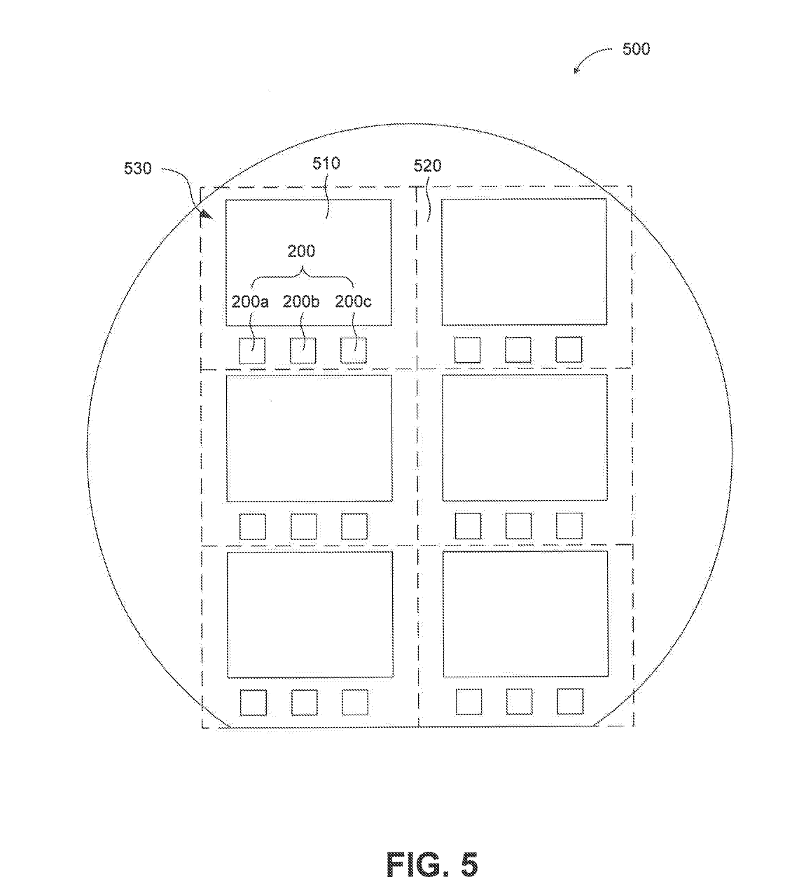

FIG. 5 schematically illustrates a plan view of a semiconductor wafer 500 formed with a plurality of test pattern structures 200, according to an embodiment of the disclosure. Semiconductor wafer 500 includes a plurality of chip regions 510 each having a predetermined electronic circuit structure formed thereon, and a plurality of scribe line regions 520 between adjacent chip regions 510. The plurality of test pattern structures 200 are repeatedly formed within scribe line regions 520.

Each one of the plurality of chip regions 510 and its surrounding scribe line regions 520 constitute an exposure region 530, which is subjected to exposure by an incident light during a photolithography process. Each exposure region 530 includes three test pattern structures 200a, 200b, and 200c having similar structures with various dimensions. For example, test pattern structures 200a, 200b, and 200c in an exposure region 530 can have different widths w1 and/or lengths l1 for box-shaped portions 222, can have different widths w2 and/or lengths l2 for openings 222a, can have different spaces s between box-shapes portions 222, and/or can have different line widths w3 for line portions 242a. However, each one of test pattern structures 200a, 200b, and 200c has the same dimension in all exposure regions 530. For example, test pattern structure 200a in the upper-left exposure region 530 has the same structure and dimension as test pattern structure 200a in the upper-right exposure region 530.

Although each exposure region 530 illustrated in FIG. 5 corresponds to a single chip region 510, the size of exposure region 530 is variable. That is, each exposure region 530 can correspond to two or more chip regions 510.

Test pattern structure 200 is formed during the fabrication process of a semiconductor device within chip region 530. In one embodiment of the disclosure, first layer 220, insulation layer 230, and second layer 240 of test pattern structure 200 are respectively formed by the same process and have the same composition as a first metal (M1) layer, a first inter-metal dielectric (IMD) layer, and a second metal (M2) layer of a semiconductor device in chip region 530. When a cut-off is formed in second layer 240 of test pattern structure 200, one or more cut-offs may also have been formed in the M2 layer of the semiconductor device. Thus, test pattern structure 200 of this embodiment can be used to monitor for the existence of cut-offs within the M2 layer of the semiconductor device formed in chip region 530, thus monitoring the fabrication process of the M2 layer of the semiconductor device.

In another embodiment of the disclosure, first layer 220, insulation layer 230, and second layer 240 of test pattern structure 200 are respectively formed by the same process and have the same composition as the M2 layer, a second ND layer, and a third metal (M3) layer of the semiconductor device in chip region 530. The test pattern structure 200 of this embodiment can be used to monitor for the existence of cut-offs within the M3 layer of the semiconductor device in chip region 530.

In still another embodiment of the disclosure, first layer 220, insulation layer 230, and second layer 240 of test pattern structure 200 are respectively formed by the same process and have the same composition as a polysilicon layer, a field oxide layer, and the M1 layer of the semiconductor device in chip region 530. The test pattern structure 200 of this embodiment can be used to monitor for the existence of cut-offs within the M1 layer of the semiconductor device in chip region 530.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A test pattern structure, comprising:
a substrate;
a first layer formed over the substrate and including a plurality of box-shaped portions; and
a second layer formed over the first layer and including a line portion that continuously extends across centers of the box-shaped portions.

2. The test pattern structure of claim 1, further including an insulation layer formed between the first layer and the second layer.

3. The test pattern structure of claim 2, wherein the insulation layer is formed of one or more electrically insulating materials.

4. The test pattern structure of claim 1, wherein the second layer is formed of one or more electrically conductive materials.

5. The test pattern structure of claim 1, wherein the first layer is formed of one or more electrically conductive materials.

6. The test pattern structure of claim 1, wherein the second layer includes step portions corresponding to edges of the box-shaped portions of the first layer.

7. The test pattern structure of claim 1, wherein the second layer includes terminal portions formed at opposite ends of the line portion.

8. A method for monitoring existence of cut-offs ithin a layer, comprising:
forming a test pattern structure within a scribe line region of a semiconductor wafer, the forming the test pattern structure comprising:
forming a first layer over a substrate, the first layer including a plurality of box-shaped portions; and
forming a second layer over the first layer, the second layer including a line portion that continuously extends across centers of the box-shaped portions;
applying a voltage between opposite ends of the line portion of the second layer;
measuring a resistance between the opposite ends of the line portion of the second layer; and
determining whether a cut-off exists within the line portion of the second layer based on the measured resistance.

9. The method of claim 8, wherein the determining whether a cut-off exists within the line portion of the second layer further includes:
determining that a cut-off exists within the line portion of the second layer when the measured resistance is greater than a predetermined resistance value; and
determining that a cut-off does not exist within the line portion of the second layer when the measured resistance is less than or equal to a predetermined resistance value.

10. The method of claim 8, further including forming an insulation layer between the first layer and the second layer.

11. The method of claim 10, wherein the forming the insulation layer includes forming the insulation layer to include one or more electrically insulating materials.

12. The method of claim 8, wherein the forming the second layer includes forming the second layer to include one or more electrically conductive materials.

13. The method of claim 8, wherein the forming the first layer includes forming the second layer to include one or more electrically conductive materials.

14. The method of claim 8, wherein the forming the second layer includes forming terminal portions at opposite ends of the line portion.

15. A semiconductor wafer, comprising:
a chip region;
a scribe line region surrounding the chip region; and
a test pattern structure formed in the scribe line region, the test pattern structure comprising:
a substrate;
a first layer formed over the substrate and including a plurality of box-shaped portions; and
a second layer formed over the first layer and including a line portion that continuously extends across the centers of the box-shaped portions.

16. The semiconductor wafer of claim 15, wherein the test pattern structure further includes an insulation layer formed between the first layer and the second layer.

17. The semiconductor wafer of claim 16, wherein the insulation layer is formed of one or more electrically insulating materials.

18. The semiconductor wafer of claim 15, wherein the second layer is formed of one or more electrically conductive materials.

19. The semiconductor wafer of claim 15, wherein the first layer is formed of one or more electrically conductive materials.

20. The semiconductor wafer of claim 15, wherein the second layer includes terminal portions formed at opposite ends of the line portion.
